(19) United States
(12) Patent Application Publication
(10) Pub. No.: US 2008/0227379 A1
(43) Pub. Date: Sep. 18, 2008

(54) Magnetic fan-attaching structure and magnetic attaching element thereof

(76) Inventor: Chung-Liang Hung, Taoyuan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/724,162

(22) Filed: Mar. 15, 2007

(51) Int. Cl. H05K 5/00; F16B 19/00; F16B 33/00

(52) U.S. Cl. 454/184; 411/378; 411/508

(57) ABSTRACT

A magnetic fan-attaching structure and a magnetic attaching element are disclosed. The magnetic fan-attaching structure includes a fan body and at least one magnetic attaching element. The fan body has at least one through hole. The magnetic attaching element includes a main body and a magnetic unit located at the main body. The main body has a head portion and a rod body. The head portion has a contacting surface and an attaching surface that are opposite to the contacting surface. The contacting surface is linked to the rod body. The attaching surface is exposed to a side surface of the fan body. The rod body passes through the through hole to combine the magnetic attaching element with the fan body. Thereby, the fan body can be easily and rapidly installed at the desired location by a magnetic-absorbing method. It is convenient for users.

### BACKGROUND OF THE INVENTION

1. Field of the Invention

The present invention relates to a fan structure. In particular, this invention relates to a magnetic fan-attaching structure in which a magnetic attaching element is installed in the through hole of the fan body.

2. Description of the Related Art

Because a lot of circuit boards and electronic components are located in a computer housing, a large amount of heat is generated by the graphics card, chips, and integrated circuits located on the circuit board in the computer housing when the computer is operating. The temperature inside the computer housing therefore rises. If the temperature in the housing exceeds the operating temperature specifications of the electronic components, the electronic components will be damaged and the computer will shut down. Therefore, cooling holes are formed on the housing and fans are installed in the housing. When the computer is operating, the heat generated from the electronic components in the housing is exhausted to the outside of the housing via the cooling holes due to the air convection caused by the fan.

FIG. 1 shows a fan structure of the prior art. At four corners of the fan body 10a, there is a through hole 11a. The computer housing 20a has fastening holes 21a that correspond to the through holes 11a, and a plurality of cooling holes 22a. The screws 30a pass through the fastening holes 21a and are screwed in the through holes 11a so that the fan body 10a is fastened on the computer housing 20a. The fan body 10a exhausts the heat in the computer housing 20a to outside of the computer housing 20a via the cooling holes 22a.

However, the fan structure of the prior art merely screwed on to the fastening holes 21a of the computer housing 20a via the through holes 11a and the screws 30a, the air-supplying direction and the air-exhausting direction could not be easily changed, and the assembling process was complex. The fan could not be rapidly installed to another location or an additional fan could not be added to enhance cooling.

### SUMMARY OF THE INVENTION

One particular aspect of the present invention is to provide a magnetic fan-attaching structure. It utilizes a magnetic attaching element to combine a through hole preformed on the fan body to form the magnetic fan-attaching structure. Therefore, it is convenient and rapid to install or add a fan to a desired location through the magnetic attaching method. The user can easily install or add a fan in the computer housing.

Another particular aspect of the present invention is to provide a magnetic fan-attaching structure. It utilizes the magnetic attaching element located on the through hole of the fan body to rapidly adjust the air-supplying direction and the air-exhausting direction of the fan.

The magnetic fan-attaching structure includes a fan body having two opposite side surfaces, and at least one magnetic attaching element having a main body and a magnetic unit. The fan body has at least one through hole. The main body has a head portion and a rod body. The head portion has a contacting surface and an attaching surface that is opposite to the contacting surface. The contacting surface is linked to the rod body. The attaching surface is exposed to a side surface of the fan body. The magnetic unit is located on the head portion of the main body. The magnetic unit forms a magnetic-absorbing surface that corresponds to the attaching surface. The rod body passes through the through hole to combine the magnetic attaching element with the fan body.

In another embodiment, the magnetic attaching element includes a main body having a head portion and a rod body, and a magnetic unit located at the head portion of the main body. The head portion has a contacting surface and an attaching surface that is opposite to the contacting surface. The contacting surface is linked to the rod body. The magnetic unit forms a magnetic-absorbing surface that corresponds to the attaching surface.

The present invention combines the magnetic element with the through hole of the fan body so that the fan body can be magnetically absorbed on the computer housing or another location by using the magnetic element. Users can add fans in the housing according as per their requirements, and rapidly change the air-supplying direction and the air-exhausting direction of the fan.

For further understanding of the invention, reference is made to the following detailed description illustrating the embodiments and examples of the invention. The description is only for illustrating the invention and is not intended to be considered limiting of the scope of the claim.

### BRIEF DESCRIPTION OF THE DRAWINGS

The drawings included herein provide a further understanding of the invention. A brief introduction of the drawings is as follows:

FIG. 1 is a perspective view of the fan of the prior art combined with a computer housing;

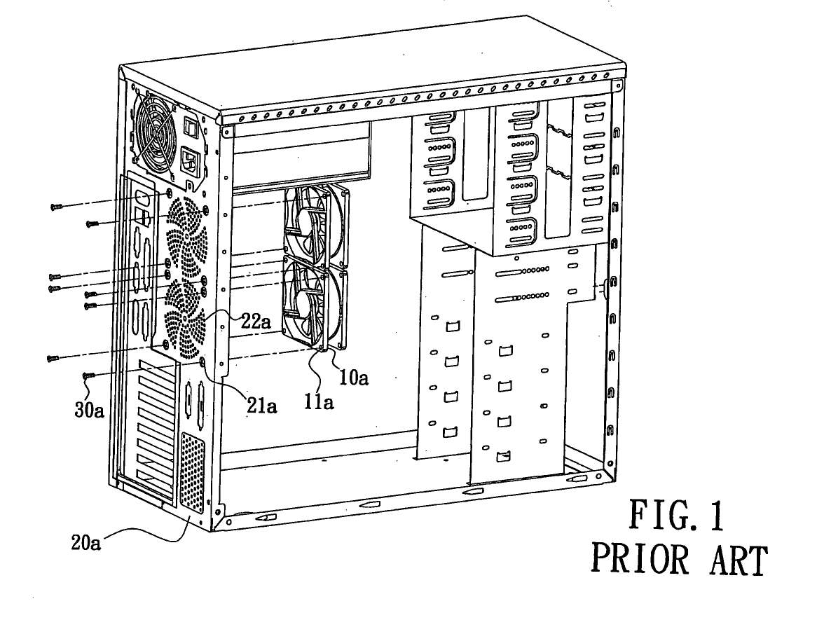

FIG. 2 is an exploded perspective view of the magnetic fan-attaching structure and the magnetic attaching element of the first embodiment of the present invention;

FIG. 3 is an assembly perspective view of the magnetic fan-attaching structure and the magnetic attaching element of the first embodiment of the present invention;

FIG. 4 is a perspective view of the magnetic attaching element of the second embodiment of the present invention;

FIG. 5 is a perspective view of the magnetic attaching element of the third embodiment of the present invention;

FIG. 6 is a perspective view of the magnetic attaching element of the fourth embodiment of the present invention;

FIG. 7 is a cross-sectional view of the magnetic attaching element of the fourth embodiment of the present invention combined with the fan; and

FIG. 8 is part of a cross-sectional view of the magnetic attaching element of the fifth embodiment of the present invention combined with the fan.

### DETAILED DESCRIPTION OF THE PREFERRED EMBODIMENTS

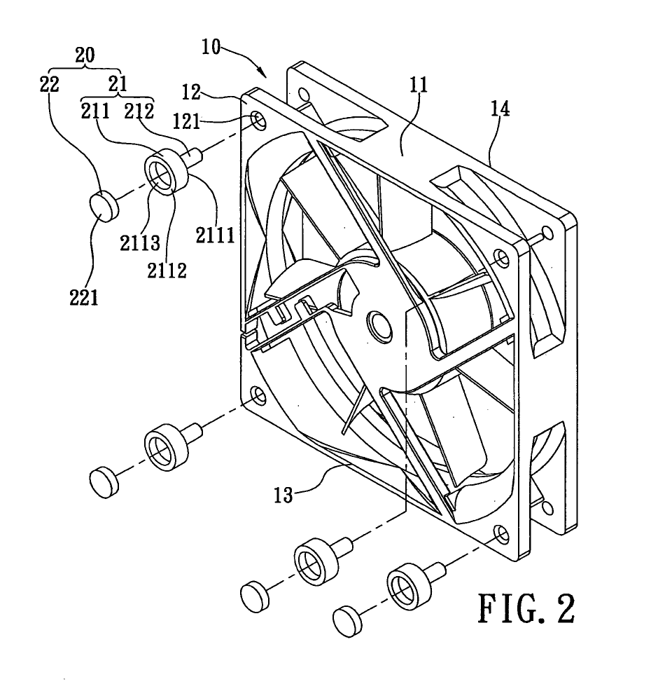

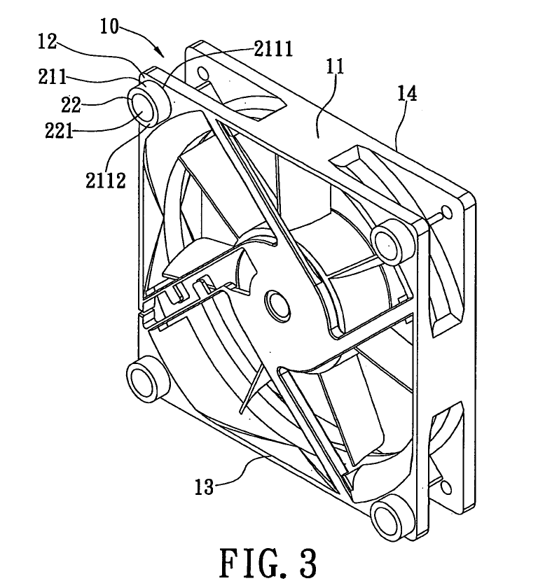

Reference is made to FIGS. 2 and 3. The magnetic fan-attaching structure includes a fan body 10, and four magnetic attaching elements 20.

The fan body 10 has a frame body 11. The edges of the front side and the rear side of the frame body 11 extend outwards to form four fastening boards 12. The four fastening boards 12 are located at the four corners of the fan body 10. Each fastening board 12 has a through hole 121. The frame body 11 has a front side surface and a rear side surface that is opposite to each other. The front side surface is an air-exhausting surface 13. The rear side surface is an air-supplying surface 14. The air enters into the fan body 10 via the air-supplying surface 14, and is exhausted to outside of the fan body 10 via the air-exhausting surface 13.

Each magnetic attaching element 20 includes a main body 21 and a magnetic unit 22. The main body 21 has a head portion 211 and a rod body 212. In this embodiment, the edge of the head portion 211 is circular. The head portion 211 has a contacting surface 2111 and an attaching surface 2112 that is opposite to the contacting surface 2111. The head portion 211 has a receiving space 2113 for receiving the magnetic unit 22. In this embodiment, the receiving space 2113 is formed at the center of the attaching surface 2112 of the head portion 211 and is concave. Alternatively, the receiving space 2113 can also be located in the interior of the head portion 211 (not shown in the figure). Thereby, the magnetic unit 22 is embedded in the head portion 211 and does not expose to outside of the magnetic attaching element 20. The rod body 212 has a circular-column shape. The rod body 212 is linked to the contacting surface 2111, and the outer diameter of the rod body 212 is larger than the inner diameter of the through hole 121 of the fan body 10.

The magnetic unit 22 is made of magnetic material, such as a magnet, a loadstone, etc. The magnetic unit 22 forms a magnetic-absorbing surface 221 that corresponds to the attaching surface 2112. The magnetic unit 22 is received in the receiving space 2113 by a pressing method, a pasting method, or a putting method, etc. The magnetic unit 22 is located at the head portion 211 of the main body 21 so that the magnetic-absorbing surface 221 of the magnetic unit 22 is exposed to the opening end of the receiving space 2113. The magnetic-absorbing surface 221 of the magnetic unit 22 protrudes from the attaching surface 2112 of the head portion 211 or caves in to the attaching surface 2112 of the head portion 211. Alternatively, at the edge of the magnetic unit 22, there is a sawtooth-shaped convex portion (not shown in the figure). On the inner wall of the receiving space 2113, there is a plurality of concave portions that correspond to the convex portion (not shown in the figure). Thereby, the magnetic unit 22 is tightly combined with the head portion 211 of the main body 21.

When the magnetic attaching elements 20 are combined with the fan body 10, the rod body 212 of the main body 21 is pressed into the through hole 121 of the fan body 10 that is close to the air-exhausting surface 13. The rod body 21 passes through the through hole 121 to combine the magnetic attaching element 20 with the fan body 10, and the attaching surface 2112 of the main body 21 is exposed to the air-exhausting surface 13 of the fan body 10. In this embodiment, the magnetic attaching element 20 is combined with the air-exhausting surface 13 of the fan body 10. Alternatively, the attaching element 20 can also be combined with the air-supplying surface 14 of the fan body 10 in the same way. The main body 21 can also be made of a magnet. The magnetic unit 22 is integrated with the main body 21 into one piece.

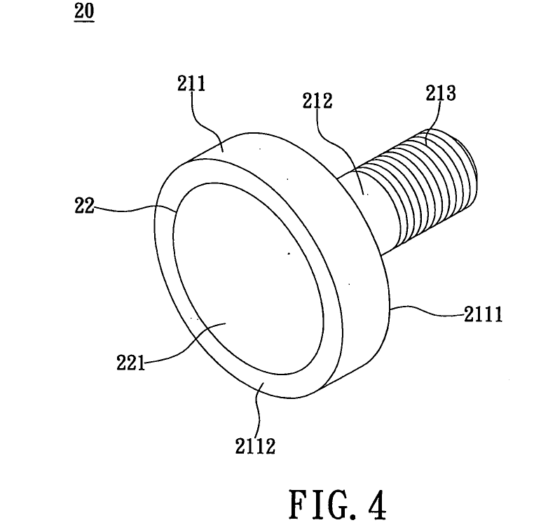

Reference is made to FIG. 4. The magnetic attaching element 20 further includes a holding portion. In this embodiment, the holding portion is a thread 213. The thread 213 is formed on the surface of the rod body 212. The rod body 212 is screwed onto the through hole 121 of the fan body 10 via the thread 213 (reference is made to FIG. 2) so that the magnetic attaching element 20 is fastened onto the fan body 10 via the holding portion (the thread 213).

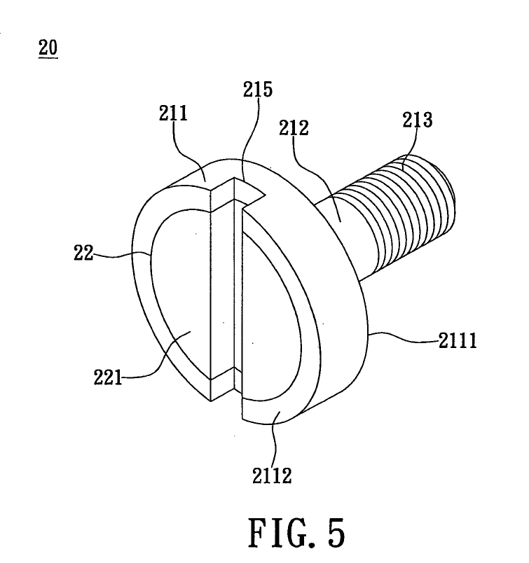

Reference is made to FIG. 5. The attaching surface 2112 of the head portion 211 further includes a concave slot 215. The concave slot 215 has an I-shape and passes through the magnetic unit 22. Alternatively, the attaching surface 2112 forms two concave slots 215 which are vertical to each other (not shown in the figure). Furthermore, the edge of the head portion 211 is hexagon so that it cooperates with an I-shaped screwdriver, a cross screwdriver, or a hexagon bushing spanner. Therefore, users can use the described tools to install or uninstall the magnetic attaching element 20 from the through hole 121 of the fan body 10 to change the air-supplying direction or the air-exhausting direction of the fan body 10.

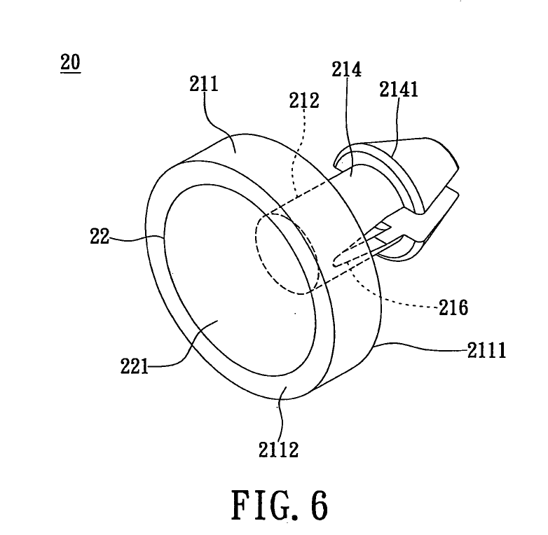

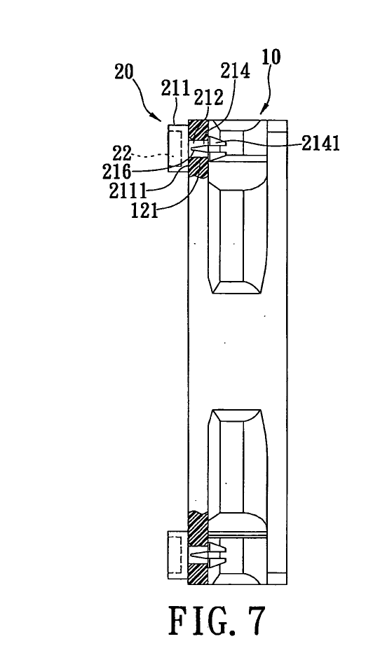

Reference is made to FIGS. 6 and 7. Another holding portion is disclosed. The holding portion includes at least two claw portions 214. The two claw portions 214 are formed by extending from the rod body 212 and departing from the head portion 211. There is a cutting ditch 216 between the two claw portions 214 so that the two claw portions 214 are flexible. One end of each claw portion 214 is a free end and protrudes outwards to form a wedged body 2141. One end of the rod body 212 that departs from the head portion 211 protrudes outwards to from the wedged body 2141.

The through hole 121 of the fan body 10 passes through the front side and the rear side of the fastening board 12. The contacting surface 2111 of the magnetic attaching element 20 contacts the fastening board 12 that is close to the air-exhausting surface 13. The wedged body 2141 of the holding portion passes through the through hole 121 and contacts another end of the fastening board 12 so that the magnetic attaching element 20 is fastened onto the fan body 10 via the holding portion.

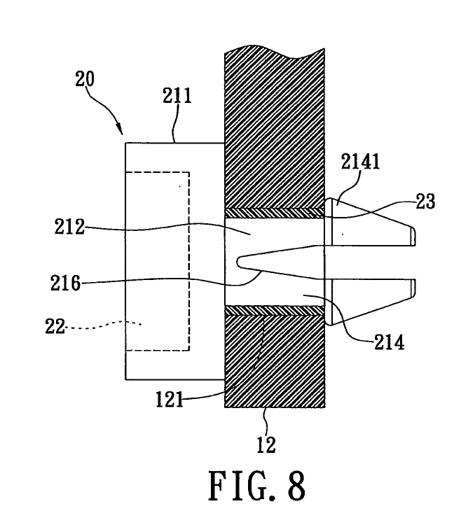

Reference is made to FIG. 8. The rod body 212 is covered with a flexible material cushion element 23. The flexible material cushion element 23 is clipped between the inner wall of the through hole 121 and the surface of the rod body for absorbing vibrations when the fan body 10 is rotating to lower the noise.

Furthermore, besides the magnetic attaching element 20 being combined with the fan body 10, the magnetic attaching element 20 can also be combined with a fan screen, a fan filtering screen, or a fan air-guiding protection screen, etc to install the above elements at the desired locations by a magnetic-absorbing method.

The present invention utilizes the through hole 121 of the fan body 10 to combine with a magnetic attaching element 20 to make the fan body 10 be magnetically attached on the device that needs to be cooled, such as a housing of a power supply, a housing of a backup power supply, a housing of a computer, a housing of an industrial computer, a housing of a server, a housing of a UPS, a housing of a disk array external box, a housing of an external hard disk box, a housing of an external optical drive, a housing of a keyboard, a housing of a laptop cooling board, a housing of a projector, a housing of a medical measuring equipment, or other housings having a fan, etc. The screw is not required. The user easily and rapidly installs the fan body 10 to the desired location. If the magnetic attaching element 20 is combined with the through hole 121 that is close to the air-exhausting surface 13 to make the fan body 10 exhaust the air via the air-exhausting surface 13, the user merely changes the magnetic attaching element 20 to combine with the through hole 121 that is close to the air-supplying surface 14 so as to make the fan body 10 supply the air from the air-supplying surface 14. Thereby, the user can rapidly change the air-supplying direction and the air-exhausting direction of the fan body 10. It is convenient for the user.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. A magnetic fan-attaching structure, comprising:
a fan body having two opposite side surfaces, wherein the fan body has at least one through hole; and
at least one magnetic attaching element having a main body and a magnetic unit, wherein the main body has a head portion and a rod body, the head portion has a contacting surface and an attaching surface that is opposite to the contacting surface, the contacting surface is linked to the rod body, the attaching surface is exposed to a side surface of the fan body, the magnetic unit is located at the head portion of the main body, the magnetic unit forms a magnetic-absorbing surface that corresponds to the attaching surface, and the rod body passes through the through hole to combine the magnetic attaching element with the fan body.

2. The magnetic fan-attaching structure as claimed in claim 1, wherein the rod body of the magnetic attaching element is pressed into the through hole of the fan body.

3. The magnetic fan-attaching structure as claimed in claim 1, wherein the rod body of the magnetic attaching element includes a holding portion, and the magnetic attaching element is fastened on the fan body via the holding portion.

4. The magnetic fan-attaching structure as claimed in claim 3, wherein the holding portion is a thread, the thread is formed on the surface of the rod body, and the rod body is screwed in the through hole of the fan body via the thread.

5. The magnetic fan-attaching structure as claimed in claim 3, wherein the holding portion includes at least one wedged body, the wedged body is formed by protruding outwards from one end of the rod body that departs from the head portion, the fan body has a fastening board that corresponds to the through hole, the through hole passes through two sides of the fastening board, the contacting surface of the head portion and the wedged body of the holding portion respectively contact the two sides of the fastening board.

6. The magnetic fan-attaching structure as claimed in claim 5, wherein the holding portion includes at least two claw portions, the two claw portions extend from the rod body and depart from the head portion, there is a cutting ditch between the two claw portions, and one end of each of the claw portions is a free end and protrudes outwards to form the wedged body.

7. The magnetic fan-attaching structure as claimed in claim 1, wherein the rod body is covered with a flexible material cushion element, and the flexible material cushion element is clipped between the inner wall of the through hole and the surface of the rod body.

8. A magnetic attaching element, comprising:
a main body having a head portion and a rod body, wherein the head portion has a contacting surface and an attaching surface that is opposite to the contacting surface, and the contacting surface is linked to the rod body; and
a magnetic unit located at the head portion of the main body, wherein the magnetic unit forms a magnetic-absorbing surface that corresponds to the attaching surface.

9. The magnetic attaching element as claimed in claim 8, wherein the head portion has a receiving space, and the magnetic unit is received in the receiving space.

10. The magnetic attaching element as claimed in claim 9, wherein the attaching surface of the head portion caves inwards to form the receiving space, and the magnetic-absorbing surface of the magnetic unit is exposed to an opening of the receiving space.

11. The magnetic attaching element as claimed in claim 10, wherein the magnetic-absorbing surface of the magnetic unit protrudes to the attaching surface of the head portion.

12. The magnetic attaching element as claimed in claim 10, wherein the magnetic-absorbing surface of the magnetic unit caves into the attaching surface of the head portion.

13. The magnetic attaching element as claimed in claim 9, wherein the receiving space is located in the interior of the head portion, and the magnetic unit is embedded into the head portion.

14. The magnetic attaching element as claimed in claim 9, wherein an edge of the magnetic unit includes sawtooth-shape convex portions, a plurality of concave portions caves in the inner wall of the receiving space, and the convex portions correspond to the concave portions.

15. The magnetic attaching element as claimed in claim 8, wherein the attaching surface of the head portion caves inwards to form at least one concave slot.

16. The magnetic attaching element as claimed in claim 8, wherein the main body is made of magnetic material, and the magnetic unit is integrated with the main body into one piece.

17. The magnetic attaching element as claimed in claim 8, wherein the edge of the head portion is circular.

18. The magnetic attaching element as claimed in claim 8, wherein the edge of the head portion is hexagon.

19. The magnetic attaching element as claimed in claim 8, wherein the rod body includes a holding portion.

20. The magnetic attaching element as claimed in claim 19, wherein the holding portion is a thread, and the thread is formed on the surface of the rod body.

21. The magnetic attaching element as claimed in claim 19, wherein the holding portion includes at least one wedged body, and the wedged body is formed by protruding outwards from one end of the rod body that departs from the head portion.

22. The magnetic attaching element as claimed in claim 21, wherein the holding portion includes at least two claw portions, the two claw portions extend from the rod body and depart from the head portion, there is a cutting ditch between the two claw portions, and one end of each of the claw portions is a free end and protrudes outwards to form the wedged body.

23. The magnetic attaching element as claimed in claim 8, wherein the rod body is covered with a flexible material cushion element.

24. The magnetic attaching element as claimed in claim 8, wherein the magnetic attaching element is combined with a fan screen, a fan filtering screen, or a fan air-guiding protection screen.
